(19) United States
(12) Patent Application Publication
(10) Pub. No.: US 2018/0350598 A1
(43) Pub. Date: Dec. 6, 2018

(54) BORON FILM REMOVING METHOD, AND PATTERN FORMING METHOD AND APPARATUS USING BORON FILM

(71) Applicant: Tokyo Electron Limited, Tokyo (JP)

(72) Inventors: Yoshimasa WATANABE, Yamanashi (JP); Masahiro OKA, Yamanashi (JP); Hirokazu UEDA, Yamanashi (JP)

(21) Appl. No.: 15/997,431

(22) Filed: Jun. 4, 2018

(30) Foreign Application Priority Data
Jun. 5, 2017 (JP) 2017-111209

(51) Int. Cl. H01L 21/033; H01L 21/02; H01L 21/3205; C23C 16/28; C23C 16/50; C23C 16/56

(52) U.S. Cl. CPC H01L 21/0332; H01L 21/0335; H01L 21/0337; H01L 21/02087; C23C 16/56; H01L 21/32055; C23C 16/28; C23C 16/50; H01L 21/02233

(57) ABSTRACT

In a method for removing a boron film formed on a substrate by CVD, heat treatment is performed on a part or all boron film in an oxidizing atmosphere and oxidizing a heat-treated portion. Then, an oxidized portion of the boron film is removed by water or aqueous solution containing electrolyte ions.

### CROSS-REFERENCE TO RELATED APPLICATIONS

This application claims priority to Japanese Patent Application No. 2017-111209 filed on Jun. 5, 2017, the entire contents of which are incorporated herein by reference.

### FIELD OF THE INVENTION

The present disclosure relates to a boron film removing method and a pattern forming method using a boron film.

### BACKGROUND OF THE INVENTION

Recently, along with development of a semiconductor manufacturing technology, miniaturization of semiconductor devices has progressed and, thus, semiconductor devices with a size of 10 nm or less have appeared. Further, techniques for three-dimensionally constructing semiconductor devices for higher integration of semiconductor devices advancing. Therefore, the number of thin films laminated on semiconductor wafer is increased. For example, in three-dimensional NAND flash memory, it is required to perform microprocessing of a thick laminated film having a thickness of 1 μm or more which includes a silicon oxide (SiO₂) film, a silicon nitride (SiN) or the like by dry etching.

Conventionally, an amorphous silicon film or an amorphous carbon film has been used as a hard mask for performing microprocessing. However, those films have a low etching resistance. Therefore, when those films are used as a hard mask, a film thickness needs to be increased. Accordingly, it is required to form a thick film having a thickness of 1 μm or more.

As for a next-generation hard mask material, there is examined a metal material film such as a tungsten film or the like having a higher etching resistance than that of an amorphous silicon film or an amorphous carbon film. However, it is difficult for the metal material film such as a tungsten film or the like having a high etching resistance to cope with peeling, metal contamination or the like after the dry etching.

Therefore, a boron film has been examined as a new hard mask material having a higher dry etching resistance than that of an amorphous silicon film or an amorphous carbon film and also having a high selectivity with respect to an SiO₂ film or the like. Japanese Patent Application Publication No. 2013-533376 discloses a technique for forming a boron film as a hard mask by CVD.

The film formed as a hard mask needs to be removed. At this time, the film may be locally removed and processed in a predetermined fine pattern in order to etch an etching target film in a predetermined shape, the film formed at an end portion (edge/bevel) of a semiconductor wafer may be locally removed, and the film may be completely removed after the function of the hard mask is accomplished. The amorphous silicon film or the amorphous carbon film used as the conventional hard mask material is removed by an O₂ plasma.

However, the boron film is hardly removed by the O₂ plasma due to its high resistance to the O₂ plasma. Therefore, the removal using liquid chemical has been studied. Japanese Patent Application Publication No. 2013-533376 discloses a technique for removing a boron film formed by CVD by liquid chemical containing acid having oxidizing power.

However, in the case of removal using the liquid chemical containing acid having oxidizing power, it difficult to locally select and remove a fine portion.

### SUMMARY OF THE INVENTION

In view of the above, the present disclosure provides a method capable of easily removing a boron film and selectively removing a fine portion locally and a method capable of forming a fine pattern by using a boron film.

In accordance with a first aspect, there is provided a method for removing a boron film formed on a substrate by CVD, which includes: performing heat treatment on a part or all of boron film in an oxidizing atmosphere and oxidizing a heat-treated portion; and removing an oxidized portion the film by water or aqueous solution containing a electrolyte ions.

In accordance with a second aspect, there is provided a method for forming a pattern by a boron film on a substrate, which includes: forming a boron film on substrate by CVD, performing heat treatment on the boron film partially in accordance with a predetermined pattern in an oxidizing atmosphere and oxidizing a heat-treated portion; and removing an oxidized portion of the boron film by water or aqueous solution containing electrolyte ions.

In accordance with a third aspect, there is provided an apparatus for forming a pattern by a boron film on a substrate, including: a heating unit configured to perform eat treatment on a boron film formed on a substrate by CVD partially in accordance with a predetermined pattern in an oxidizing atmosphere to oxidize a heat-treated portion, wherein an oxidized portion of the boron film is removed by water or aqueous solution containing electrolyte ions to form the predetermined pattern in the boron film.

### BRIEF DESCRIPTION OF THE DRAWINGS

The objects and features of the present disclosure will become apparent from the following description of embodiments, given in conjunction with the accompanying drawings, in which:

FIG. 1 is a flowchart showing a boron film removing method according to an embodiment;

FIG. 2 shows results of TDS (thermal desorption spectroscopy) of a CVD boron film;

FIG. 3 shows SEM images for explaining the state of the boron film before and after O₂ heat treatment;

FIG. 4 shows SEM images for explaining the state of the boron film before and after O₂ plasma treatment;

FIGS. 5A to 5D are process sectional views showing a first example of an embodiment in which the boron film removing method according to the embodiment is applied to pattern formation using a boron film;

FIGS. 6A to 6D are process sectional views showing a second example of the embodiment in which the boron film removing method according to the embodiment is applied to the pattern formation using the boron film;

FIGS. 7A and 7B show a first example of an embodiment in which a boron film removing method according to the embodiment is applied to local removal of a boron film at an end portion of a wafer;

FIGS. 8A and 8B show a second example of the embodiment in which the boron film removing method according to the embodiment is applied to the local removal of the boron film at the end portion of the wafer;

FIG. 9 shows SEM images of a sample of Experiment 1 before and after a boron film removal process;

FIG. 10 shows SEM images of a sample in which a PVD boron film is formed before and after the boron film removal process;

FIG. 11 shows SEM images before treatment of Experiment 2 and after heat treatment performed at different temperatures; and

FIG. 12 shows SEM images before treatment and after heat treatment performed at different temperatures for different periods of time.

### DETAILED DESCRIPTION OF THE EMBODIMENTS

Hereinafter, embodiments will be described with reference to the accompanying drawings.

(Outline of Boron Film Removing Method)

First, an outline of the boron film removing method of the present disclosure will be described.

A boron film has a higher dry etching resistance than that of an amorphous silicon film or an amorphous carbon film which has been conventionally used as a hard mask. Therefore, the boron film is suitable for a hard mask for etching a thick laminated film.

However, boron is chemically stable and has a nigh dry etching resistance. Further, boron is a material that is difficult to remove and cannot be removed by an O₂ plasma used for removing an amorphous silicon film or an amorphous carbon film as a conventional hard mask. A boron film can be removed by oxidizing liquid chemical treatment, e.g., chemical treatment using a mixture of acetic acid and sulfuric acid. However, it is difficult to selectively remove the boron film locally.

Therefore, a boron film removing process was examined.

Boron is chemically stable, whereas boron oxide (hydrolyzate) is water soluble (substantially water soluble). Thus, an oxidized boron can be easily removed. Actually, in the liquid chemical treatment of boron oxide, boron oxide is generated by liquid chemical and removed by pure water cleaning.

On the other hand, it was found that in a dry atmosphere, boron oxide is not generated even by a highly oxidizing process such as O₂ plasma treatment or the like and boron is hardly removed.

As a result of further study, it was found that a boron film formed by CVD such as plasma CVD or the like contains a considerable amount, e.g., about 10 at %, of hydrogen since a gas containing boron and hydrogen such as diborane (B₂H₆) gas or the like is used as a film forming material. Also, it was found that by performing heat treatment in an oxidizing atmosphere, hydrogen in the film is released and oxygen is taken into the film, thereby generating boron oxide. It is known that boron oxide is water soluble and easily removed by water.

Therefore, in the present disclosure, a substrate on which a CVD boron film is formed by using a gas containing hydrogen and boron as a film forming material is subjected to heat treatment in an oxidizing atmosphere containing oxygen or ozone and then to treatment using water or aqueous solution containing electrolyte ions. Accordingly, the boron film can be removed. In other words, boron is converted to boron oxide by the heat treatment, and boron oxide is dissolved and removed by the treatment using water or the like.

(Embodiment of Boron Film Removing Method)

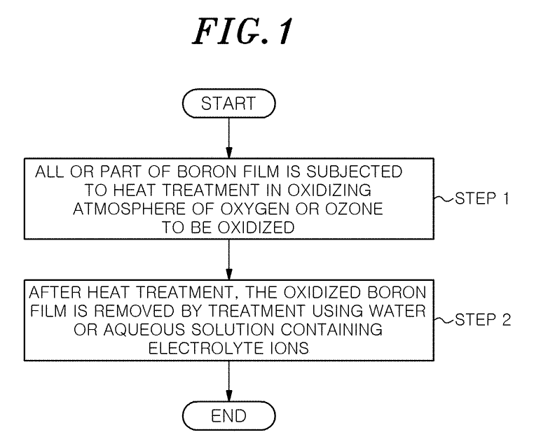

Next, the boron film removing method according to the embodiment will be described. FIG. 1 is a flowchart showing the boron film removing method according to the embodiment.

The boron film formed as a hard mask on an insulating film formed on a substrate such as a silicon wafer or the like. As for the boron film, a film formed by CVD is used. In the case of forming a boron film by CVD, diborane (B₂H₆) gas, a mixed gas of boron trichloride (BCl₃) gas and hydrogen, a gas containing boron and hydrogen such as an alkylborane gas, e.g., trimethylporane (B(CH₃)₃) gas, triethylborane (B(C₂H₅)₃) gas or the like, is used as a raw material gas. In addition to the raw material gas, inert gas such as Ar gas, He gas or the like may be contained. Although CVD may be thermal CVD or plasma CVD, the plasma CVD provides a film having a high density and a high quality. In any case, the film contains hydrogen derived from the raw material gas. In the case of CVD film formation, the amount of hydrogen contained in the film is within a range of about 3.9 at % to 11.7 at %. An actual measurement value thereof is about 10 at %.

In the present embodiment, first, all or a part of the boron film is subjected to heat treatment in an oxidizing atmosphere containing oxygen, or the like, thereby oxidizing the boron film (step 1). A heating unit used at this time is not particularly limited, and one suitable for a purpose of removal of the boron film may be used.

For example, in the case of removing the entire boron film, the substrate having boron film is accommodated in a processing chamber, and the entire substrate is heated by resistance heating or the like in a state where the inside of the processing chamber is set to an oxidizing atmosphere containing oxygen, ozone or the like.

In the case of locally removing the boron film, e.g., in the case of forming a fine pattern on the boron film, in the case of removing the boron film at the beveled portion or the edge portion of the substrate, or the like, the portion of the boron film which needs to be removed is locally heated in an oxidizing atmosphere containing oxygen, ozone or the like. As for a heating unit used at this time, it is preferable to use a laser or a lamp.

Hereinafter, the mechanism in which the boron film is oxidized by the heat treatment in the step 1 will be described.

As described above, the boron film formed by CVD contains a considerable amount of hydrogen derived from the film forming gas since a gas containing boron and hydrogen such as B₂H₆ gas or the like is used as the film forming gas. Even if the boron film thus generated is processed the an O₂ plasma as in the conventional case, oxygen is not taken into the boron film and the reaction between boron and oxygen hardly occurs.

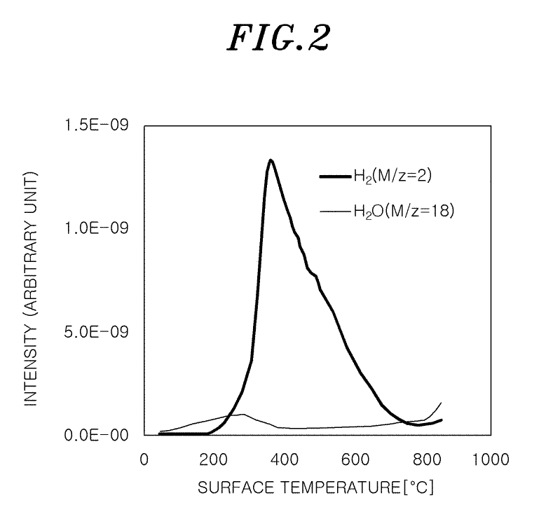

However, when the boron film is heated by the heat treatment, hydrogen contained in the film is released. FIG. 2 shows the results of thermal desorption spectroscopy (TDS) of the CVD boron film. As the temperature is increased, H₂ gas is released and the amount of released hydrogen reaches a peak at about 400° C.

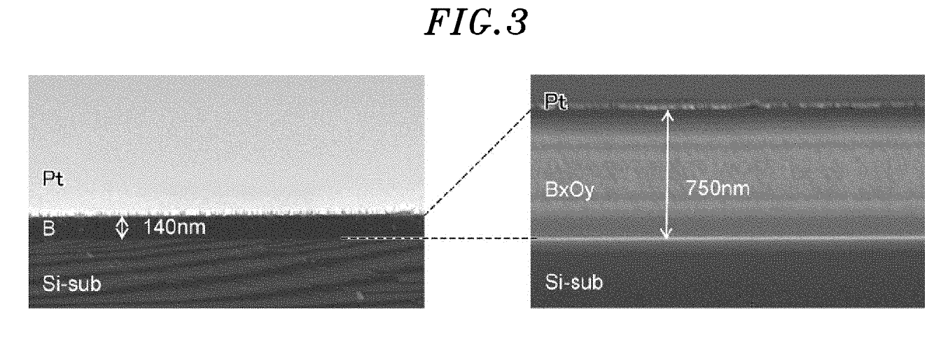

Oxygen in the atmosphere is taken into a portion from which hydrogen in the film is released and reacts with boron by heat, thereby generating boron oxide. FIG. 3 shows SEM images for explaining the state or the boron film before and after the O₂ heat treatment. The heat treatment was performed at 800° C. for 30 min in an O₂ gas atmosphere. As shown in FIG. 3, the film thickness of the boron film was increased from 140 nm to 750 nm by the O₂ heat treatment and boron oxide (BxOy) was generated. Since components such as moisture and the like other than hydrogen are contained in the boron film, the film thickness after the oxidation is greater than a film thickness calculated in consideration of oxidation of boron.

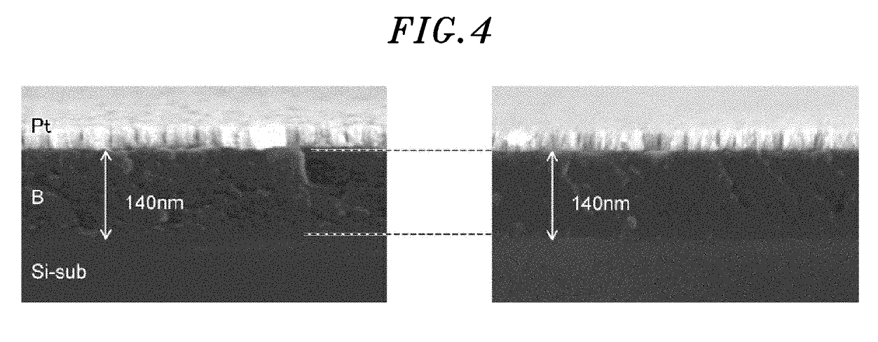

On the other hand, in the case of the O₂ plasma treatment (10 min), the boron film was the same before and after the treatment and boron oxide was not generated, as can be seen from the SEM images of FIG. 4.

The temperature of the heat treatment in the step is preferably 400° C. or higher. At a temperature lower than 400° C., the released of hydrogen and the oxidation of boron hardly occur. The temperature of the heat treatment preferably 1000° C. or less in view of equipment and more preferably 800° C. or less in view thermal diffusion of boron.

In the oxidizing atmosphere for the heat treatment, the concentration of O₂ gas or O₃ gas preferably 20% to 100%. The remaining part other than O₂ gas or O₃ gas in the oxidizing atmosphere may be an inert gas such as a nitrogen gas or a rare gas, e.g., Ar gas or He gas. The oxidizing atmosphere may be air.

Although the heat treatment time depends on the temperature, it is preferably about 1 min to 60 min. If it is less than 1 min, the release of hydrogen and the oxidation of boron hardly occur. On the other hand, when it exceeds 60 min, productivity deteriorates. If the boron film to be removed is thick and the heat treatment temperature is low, 60 min or more may be required.

Upon completion of the above-described heat treatment, the oxidized boron film is removed by treatment using water or aqueous solution containing electrolyte ions (H⁺, NH₄⁺, F, Cl, NO₃, SO₄²⁻, OH⁻ or the like) (step 2). Boron oxide dissolves in water, and thus is removed by the treatment using water or aqueous solution containing electrolyte ions. As for the aqueous solution containing electrolyte ions, it is preferable to use one other than acid having oxidizing properties.

In the treatment using water or aqueous solution containing electrolyte ions, the substrate may be immersed in pure water or aqueous solution containing electrolyte ions, or boron oxide on the substrate may be removed by stream of pure water or aqueous solution containing electrolyte ions. In the case of the removal using the stream, there may be used spin processing for supplying pure water or aqueous solution containing electrolyte ions to boron oxide while rotating the substrate by a spin chuck. Further, dry treatment for supplying steam or the like may be performed. In the case of immersing the substrate in pure water or aqueous solution containing electrolyte ions, ultrasonic vibration may be applied to the pure water by an ultrasonic generator to promote the removal of boron oxide. Although the period of time of the treatment using water or aqueous solution containing electrolyte ions depends on the treatment method, it is preferably within a range from 1 min to 30 min.

By using the above method including the steps 1 and 2, it is possible to remove all or part of the boron film formed on the substrate.

As described above, in accordance with the present embodiment, it is possible to easily remove the boron film by a simple process such as heat treatment or treatment using water without using plasma treatment (dry etching (RIE) treatment). Also, it is possible to selectively remove the boron film locally by converting the boron film into boron oxide locally and removing only the boron oxide by water or the like, instead of directly removing the boron film by chemical solution containing acid having oxidizing power as in the conventional case.

(Application to Pattern Formation Using Boron Film)

Next, an embodiment in which the boron film removing method of the above embodiment is applied to pattern formation using a boron film will be described.

### FIRST EXAMPLE

First, a first example of application to pattern formation will be described.

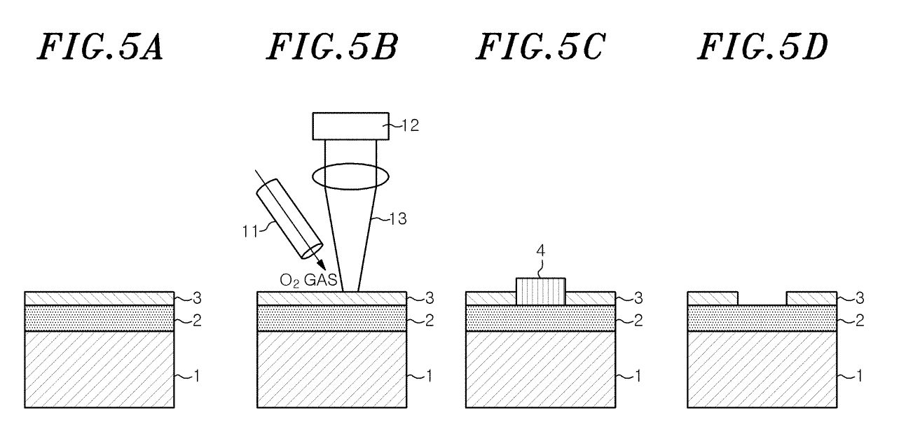

FIGS. 5A to 5D are process sectional views showing the pattern forming method of the first example.

First, a wafer having an insulating film 2 formed on a silicon substrate 1 is prepared, and a boron film 3 as a hard mask is formed thereon (FIG. 5A).

As described above, the boron film 3 is formed by CVD using a gas containing boron and hydrogen as a raw material gas. Although CVD may be thermal CVD or plasma CVD, plasma CVD provides a film having a high density and a high quality. In the case of the plasma CVD, the temperature is preferably 60° C. to 500° C. (more preferably 200° C. to 300° C.) and the pressure is preferably 0.67 Pa to 33.3 Pa. The CVD boron film contains hydrogen of about 3.9 at % to 11.7 at %.

Next, laser heating (heat treatment) is performed by locally (partially) irradiating laser 13 from a laser light source 12 as a heat source to the boron film 3 in response predetermined fine pattern while generating an oxidizing atmosphere by supplying O₂ gas or O₃ gas from an oxygen nozzle 11 to the boron film 3 (FIG. 5B). Accordingly, boron oxide 4 is generated at the portion locally heated by the laser (FIG. 5C). The heat treatment conditions at this time are the same as the above-described conditions.

Next, the wafer on which the boron oxide 4 is generated is processed by water or aqueous solution containing electrolyte ions, and the boron oxide 4 is dissolved and removed (FIG. 5D). Accordingly, a fine pattern is formed by the boron film. The treatment using water or the like at this time may be performed by immersing the wafer in pure water or the like or by streaming pure water or the like such as spin processing.

In the first example, the boron oxide is generated locally (partially) by performing laser heating in an oxidizing atmosphere, so that a fine pattern can be easily formed by a boron film. Further, a photolithography step can be omitted by using the laser heating and, thus, a fine pattern can be formed by a boron film with fewer steps.

### SECOND EXAMPLE

Next, a second example of application to pattern formation will be described.

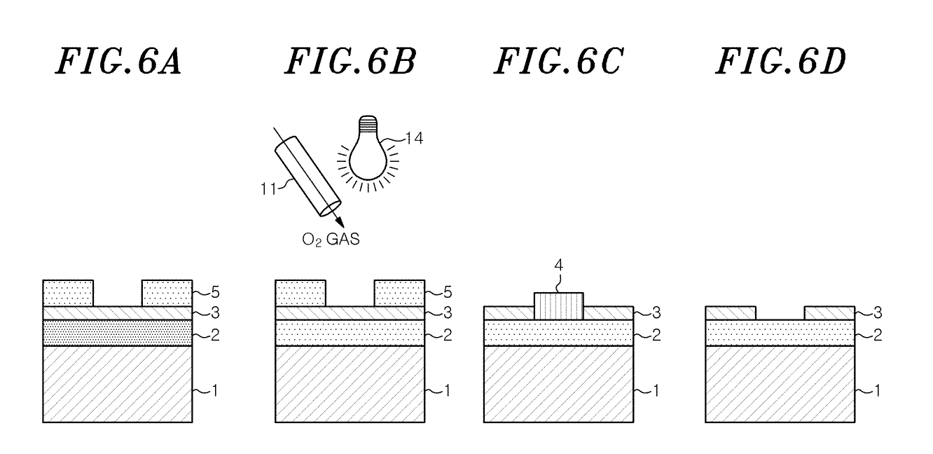

FIGS. 6A to 6D are process sectional views showing the pattern forming method of the second example.

First, a wafer having an insulating film 2 formed on a silicon substrate 1 is prepared, and a boron film 3 as a hard mask is formed thereon. A pattern is formed by a film 5 made of a resist or a mask material (insulating material, metal or the like) on the boron film 3 by utilizing photolithography and etching (FIG. 6A). As in the first example, the boron film is formed by CVD using a gas containing boron and hydrogen as a raw material gas.

Next, heat treatment is performed locally (partially) on a portion (exposed portion) corresponding to the pattern of the boron film 3 by lamp heating using a lamp light source 14 as a heat source while generating an oxidizing atmosphere by supplying O₂ gas or O₃ gas from the oxygen nozzle 11 to the boron film 3 (FIG. 6B). Accordingly, boron oxide 4 is generated at the portion corresponding to the pattern of the boron film 3 (FIG. 6C). The heat treatment conditions at this time are the same as the above-described conditions.

Next, the wafer on which the boron oxide 4 is generated is processed by water, and the boron oxide 4 is dissolved and removed (FIG. 6D). Accordingly, a fine pattern can be formed by a boron film. The treatment using water or the like at this time may b e performed by immersing the wafer in pure water or the like or by streaming pure water or the like such as spin processing.

In the second example, the boron oxide is generated by performing lamp heating in an oxidizing atmosphere on a portion corresponding to the resist pattern locally, so that a fine pattern can be easily formed by the boron film.

(Local Removal of Boron Film at End Portion of Wafer)

Next, the local removal of the boron film at the end portion of the wafer will be described.

In order to perform microprocessing in forming semiconductor devices, a pattern is formed by using photolithography. Recently, however, it is required to manage the film at the end portion (edge/bevel) of the wafer in view of particles or contamination in order to cope with the trend toward short wavelength (ArF, λ=193 nm) along with further miniaturization of a pattern and liquid immersion lithography using refraction of light.

Therefore, in the present embodiment, an example in which the boron film removing method of the above embodiment is applied to the local removal of the boron film at the end portion of the wafer will be described.

### FIRST EXAMPLE

First, a first example of the application to the local removal of the end portion of the wafer will be described.

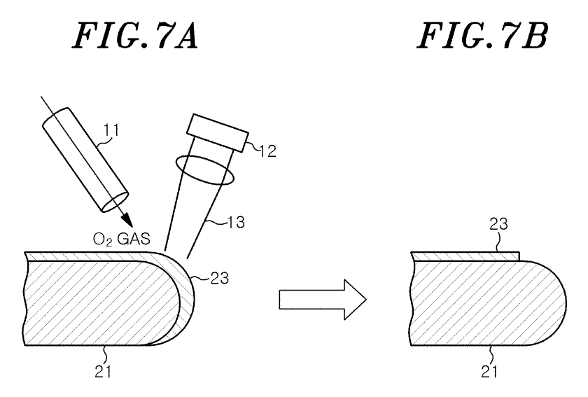

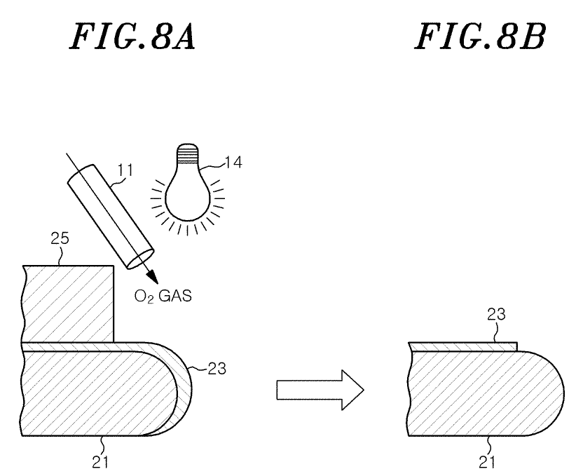

FIGS. 7A and 7B are process sectional views showing the local removal of the end portion of the wafer in the first example.

Here, laser heating (heat treatment) is performed by locally irradiating laser 13 to an end portion (edge/bevel) of a wafer 21 on which a boron film 23 as a hard mask is formed by in accordance with a predetermined fine pattern while generating an oxidizing atmosphere by supplying O₂ gas or O₃ gas from the oxygen nozzle 11 to the end portion of the wafer 21 (FIG. 7A). Accordingly, boron oxide is generated as described above and, then, the boron film 23 at the end portion (edge/bevel) is removed by treatment using water (FIG. 7B).

In the first example, the boron oxide is generated by heating the end portion locally in the oxidizing atmosphere and, thus, the boron film at the end portion (edge/bevel) of the wafer can be removed with high accuracy. Further, a photolithography step can be omitted using laser heating and, thus, the boron film at the end portion can be removed with fewer steps.

### SECOND EXAMPLE

Next, a second example of the application to the local removal of the end portion of the wafer will be described.

FIGS. 8A and 8B are process sectional views showing the local removal of the end portion of the wafer in the second example.

Here, a film 25 made of a resist or a mask material (insulting material, metal or the like) is formed on a portion of a wafer 21 on which a boron film 23 as a hard mask is formed by CVD except the end portion (edge/bevel) thereof, and heat treatment is performed by lamp heating using a lamp light source 14 as a heat source while generating an oxidizing atmosphere by supplying O₂ gas or O₃ gas om an oxygen nozzle 11 (FIG. 8A). Accordingly, the boron oxide is generated as described above and, then, the boron film 23 at the end portion (edge/bevel) is removed by treatment using water (FIG. 8B).

In the second example as well, the boron oxide is generated by heating the end portion locally and, thus, ran film at the end portion (edge/bevel) of the wafer can be easily removed with high accuracy.

(Experiment Results)

Hereinafter, the test results will be described.

### EXPERIMENT 1

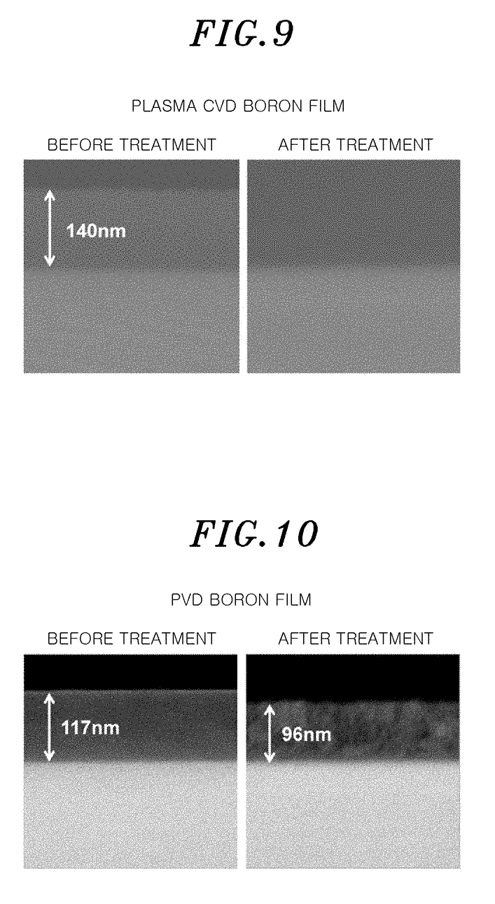

Here, there was prepared a sample in which a boron film having a thickness of 140 nm was formed on a silicon wafer by plasma CVD while using diborane gas as a film forming gas and setting a temperature to 300° C. and a pressure to 50 mTorr (6.67 Pa). Then, heat treatment was performed at 800° C. for 30 min in an O₂ gas atmosphere. Next, a boron film removing process was performed by immersing the sample in ultrasonically vibrated pure water for 30 min. FIG. 9 shows SEM images before and after the treatment. As can be seen from the images, the boron film was completely removed by the boron film removing process including the heat treatment and the treatment using pure water.

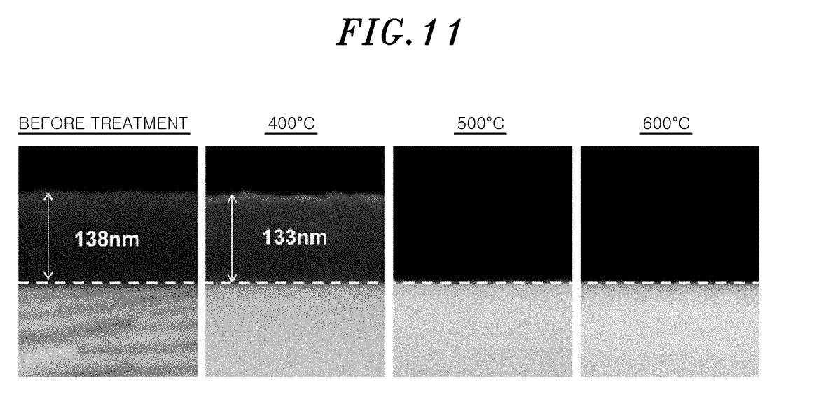

For comparison, there was prepared a sample in which a boron film having a thickness of 117 nm was formed on a silicon wafer by PVD, and the same boron removing process was performed. FIG. 10 shows SEM images before and after the treatment. As can be seen from the images, in the case of the PVD boron film, although the heat treatment was performed at high temperature of 800° C., only small amount of the boron film was removed after the pure water treatment. This is because in the case of PVD, the amount of hydrogen in the film is small and boron oxide hardly generated by the heat treatment.

### EXPERIMENT 2

Here, there was prepared a plurality of samples. In each sample, as in Experiment 1, a boron film was formed on a silicon wafer by plasma CVD while using diborane (B₂H₆) gas as a film forming gas and setting a temperature to 300° C. and a pressure to 50 mTorr (6.67 Pa). Next, heat treatment was performed in an O₂ gas atmosphere for 30 min while varying the temperature to 400° C., 500° C., and 600° C. Then, the boron film removing process of immersing the sample in ultrasonically vibrated pure water was performed for 30 min. FIG. 11 shows SEM images before the treatment and after the heat treatment performed at different temperatures. As shown in FIG. 11, in the samples in which the heat treatment temperature was set to 500° C. and 600° C., the boron film was completely removed by the boron film removing process including the heat treatment and the pure water treatment. In the sample in which the heat treatment temperature was set to 400° C., the boron film was slightly removed by the boron film removal treatment. However, a longer period of time is required to completely remove the boron film.

### EXPERIMENT 3

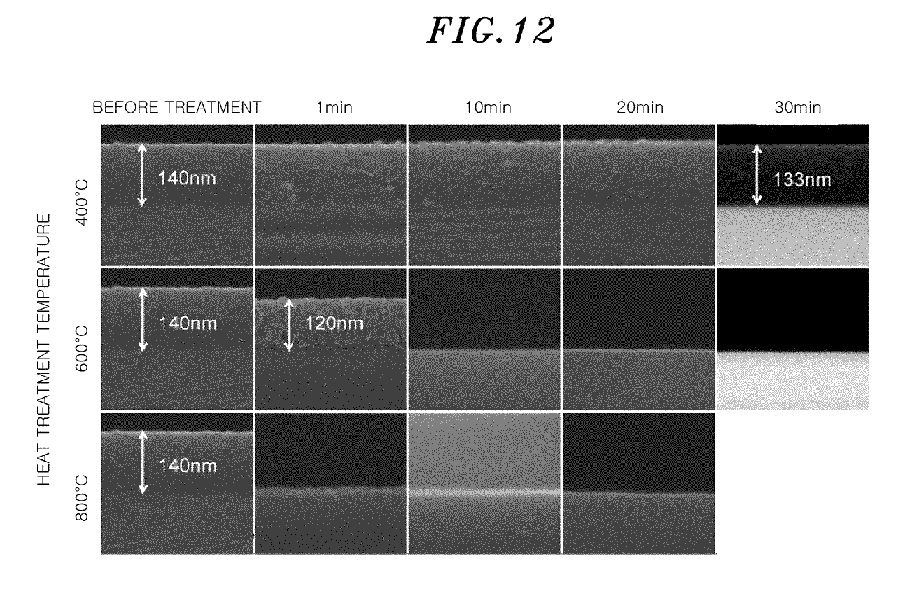

Here, there was prepared a plurality of samples. In each sample, as in Experiment 1, a boron film was formed on a silicon wafer by plasma CVD while using diborane (B₂H₆) gas as a film forming gas and setting a temperature to 300° C. and a pressure to 50 mTorr (6.67 Pa). Next, the boron film removing process of performing heat treatment in an O₂ gas atmosphere while setting the temperature to 900° C., 600° C. and 800° C. and the period of time to 10 min, 20 min and 30 min and then immersing the sample in ultrasonically vibrated pure water for 30 min was carried out. FIG. 12 shows SEM images before treatment and after the heat treatment performed at different temperature for different periods of time shown in FIG. 12, when the heat treatment was performed at 800° C. for 1 min, most of the boron film was removed. When the heat treatment was performed at 600° C. for 1 min, the thickness of the boron film was decreased from 140 nm to 120 nm. When the heat treatment was performed at 600° C. for 10 min, most of the boron film was removed. When the heat treatment was performed at 400° C. for 30 min, the boron film was slightly removed as in Experiment 2. In that case, a longer period of time is required to completely remove the boron film.

(Other Applications)

While the embodiments have been described, the present disclosure is not limited to the above embodiments, and various modifications can be made within the scope of the present disclosure.

For example, in the above embodiments, the boron film was used as a hard mask. However, the present disclosure is not limited thereto, and the boron film may also be used as a diffusion barrier film for a thin film.

In the above embodiments, the heat treatment in an oxidizing atmosphere is performed by laser heating, lamp heating, and resistance heating. However, it is possible to employ various methods and devices depending on types or purposes of removal of the boron film. Therefore, the heating method or the heating apparatus is not limited.

In the above embodiments, the example in which laser heating and lamp heating are used in forming a pattern by a boron film has been described. However, the present disclosure is not limited thereto as long as the heating can be performed locally (partly) in an oxidizing atmosphere in accordance with a predetermined pattern.

In the above embodiments, the example in which the boron film formed on the insulating film on the wafer (silicon wafer) is removed and the pattern is formed has been described. However, the present disclosure is not limited thereto and may also be applied to removal of a boron film formed on various materials or pattern formation.

While the present disclosure has been shown and described with respect to the embodiments, it will be understood by those skilled in the art that various changes and modifications may be made without departing from the scope of the present disclosure as defined in the following claims.

What is claimed is:

1. A method for removing a boron film formed on a substrate by CVD, comprising:
performing heat treatment on a part or all of the boron film in an oxidizing atmosphere and oxidizing a heat-treated portion; and
removing an oxidized portion the boron film by water or aqueous solution containing electrolyte ions.

2. The method of claim 1, wherein the oxidizing atmosphere contains oxygen or ozone.

3. The method of claim 1, wherein the electrolyte ions include any of H⁺, NH₄⁺, F⁻, Cl⁻, NO₃⁻, SO₄²⁻, and OH⁻.

4. The method of claim 3, wherein the aqueous solution containing electrolyte other than acid having oxidizing properties.

5. The method of claim wherein the boron film is formed by using a raw material gas containing boron and hydrogen.

6. The method of claim 1, wherein the boron film is formed by plasma CVD.

7. The method of claim 1, wherein said performing the heat treatment is performed at a temperature ranging from 400° C. to 1000° C.

8. The method of claim 1, wherein said performing the heat treatment is performed for 1 min to 60 min.

9. The method of claim 1, wherein said performing the heat treatment is performed in an atmosphere having an oxygen gas concentration or an ozone gas concentration of 20% to 100%.

10. The method of claim 1, wherein said performing the heat treatment is performed by laser heating.

11. The method of claim 1, wherein said performing the heat treatment is performed by lamp heating.

12. The method of claim 1, wherein said removing is performed by immersing the substrate in pure water or aqueous solution containing electrolyte ions.

13. The method of claim 12, wherein ultrasonic vibration is applied to the pure water or the aqueous solution containing electrolyte ions in which the substrate is immersed.

14. The method of claim 1, wherein said removing is performed by supplying stream of pure water or aqueous solution containing electrolyte ions to the substrate.

15. A method for forming a pattern by a boron film on a substrate, comprising:
forming a boron film on a substrate by CVD,
performing heat treatment on the boron film partially in accordance with a predetermined pattern in an oxidizing atmosphere and oxidizing a heat-treated portion; and
removing an oxidized portion of the boron film by water or aqueous solution containing electrolyte ions.

16. An apparatus for forming a pattern by a boron film on a substrate, comprising:
a heating unit configured to perform heat treatment on a boron film formed on a substrate by CVD partially in accordance with a predetermined pattern in an oxidizing atmosphere to oxidize a heat-treated portion,
wherein an oxidized portion of the boron film is removed by water or aqueous solution containing electrolyte ions to form the predetermined pattern in the boron film.
